(19) United States
(12) Patent Application Publication
(10) Pub. No.: US 2023/0266372 A1
(43) Pub. Date: Aug. 24, 2023

(54) INSULATION RESISTANCE TESTER

(71) Applicants: HYUNDAI MOTOR COMPANY, Seoul (KR); KIA CORPORATION, Seoul (KR)

(72) Inventor: Kyung Mo KIM, Hwaseong-si (KR)

(21) Appl. No.: 17/992,018

(22) Filed: Nov. 22, 2022

(30) Foreign Application Priority Data
Feb. 18, 2022 (KR) 10-2022-0021391

(51) Int. Cl. G01R 27/02; G01R 31/385; G01R 1/067

(52) U.S. Cl. CPC G01R 27/025; G01R 31/385; G01R 1/067

(57) ABSTRACT

An insulation resistance tester for testing for insulation resistance of a battery includes a solution supply unit, and a test unit configured to receive a conductive solution from the solution supply unit and to establish a contact with a test target through the conductive solution such that insulation resistance of the test target is measured.

### CROSS-REFERENCE TO RELATED APPLICATION

This application claims under 35 U.S.C. § 119(a) the benefit of priority to Korean Patent Application No. 10-2022-0021391 filed on Feb. 18, 2022, the entire contents of which are incorporated herein by reference.

### BACKGROUND

### (a) Technical Field

The present disclosure relates to an insulation resistance tester and, more particularly, to an insulation resistance tester for testing for insulation resistance of a battery.

### (b) Background Art

Electric vehicles driven by a motor instead of an engine include a battery configured to store electric power supplied to the motor. In the battery for electric vehicles, a plurality of cells are assembled into a battery module, and a plurality of modules are assembled and finally manufactured into a battery pack to be mounted in the electric vehicle. A predetermined number of cells are brought into contact with each other and then are assembled into the module to impart a required capacity to the battery.

A bonding process is carried out to hold adjoining cells together during module assembling. During this process, insulation between the cells may be damaged due to a foreign metal material, a jig, or a burr. Accordingly, testing for insulation resistance is required on a finished module before the modules are assembled into the battery pack.

Cell types depending on a packing material of the cell can be categorized into a pouch type, a prismatic type, a cylindrical type, and the like. As illustrated in FIG. 1A, in case of a pouch-type cell C, a unit cell having an anode 20 and a cathode 30 separated from each other by a separator 10 is accommodated in a pouch 40. The pouch 40 includes an outer insulation layer 42, an aluminum layer 44, and an inner insulation layer 46 in this order, starting from the outside of the pouch 40. As illustrated in FIG. 1B, pouch-type cells C are brought into contact with each other, and by connection of a bus bar 50 thereto, a module M is completed. Each module M is accommodated in an enclosure 60 made of metal. In FIG. 1B, reference numerals 70, 80, and 90 refer to a positive terminal, a negative terminal, and an insulation plastic material, respectively.

In case of the pouch-type cell C, in order to test for insulation resistance of an individual cell in the module, an end cross-section of the pouch must be exposed to the outside even in a finished module. In addition, it is preferable that a space is present where a probe for testing insulation resistance can enter and make a contact with the cross-section of an individual pouch.

If such conditions cannot be met, as an alternative, insulation resistance of the module may be tested using the enclosure 60 of the module. However, if the insulation is damaged due to damages on the pouch within the module, insulation failure may not be detected when the enclosure of the module is tested. In this case, it is determined that the module operates properly and is sent out for actual operation, but an insulation problem may appear later during operation.

The above information disclosed in this Background section is only for enhancement of understanding of the background of the disclosure and accordingly it may include information that does not form the prior art that is already known in this country to a person of ordinary skill in the art.

### SUMMARY OF THE DISCLOSURE

The present disclosure has been made in efforts to solve the above problems, and an object of the present disclosure is to provide an insulation resistance tester having improved reliability.

The present disclosure is not limited to the above-mentioned object. An object not mentioned can be clearly understood, from the following description, by a person of ordinary skill in the art to which the present disclosure pertains.

Exemplary embodiments of the present disclosure are configured as follows to achieve the object of the disclosure as mentioned above and to perform a characteristic function thereof.

According to one embodiment, the tester includes a solution supply unit, and a test unit configured to receive a conductive solution from the solution supply unit and to establish a contact with a test target through the conductive solution such that insulation resistance of the test target is measured. According to some embodiments, the tester comprises a pad wetted with a conductive solution, a test unit configured to be supplied with the conductive solution from the pad and to make a contact with a test target through the conductive solution to measure insulation resistance of the test target, and a first controller configured to receive the measured insulation resistance from the test unit and to determine whether the insulation resistance is normal.

According to some embodiments, a method of controlling the insulation resistance tester including steps implemented by a controller comprises receiving in real time electric resistance of a pad supplied with a conductive solution from a storage container, comparing the received electric resistance with preset limits, and controlling on the basis of a result of the comparison operation of an adjustment valve configured to switch a flow direction of the conductive solution between the storage container and the pad.

According to the present disclosure, there is provided the insulation resistance tester with improved reliability by making a contact between an end portion of a pouch and a test probe through the conductive solution.

The present disclosure is not limited to the above-mentioned advantageous effect. An advantageous effect not mentioned can be clearly recognized, from the following description, by a person of ordinary skill in the art.

### BRIEF DESCRIPTION OF THE DRAWINGS

The above and other features of the present disclosure will now be described in detail with reference to certain exemplary examples thereof illustrated in the accompanying drawings which are given herein below by way of illustration only, and thus are not limitative of the present disclosure, and wherein:

FIG. 1A is a schematic cross-sectional view illustrating a pouch-type cell of a battery;

FIG. 1B is a schematic side view illustrating a battery module;

FIGS. 2A, 2B, 2C, and 2D are views each illustrating an example where a cross section of a pouch and a test probe are brought into contact with each other;

FIG. 3 is a view illustrating an insulation resistance tester according to an embodiment of the present disclosure;

FIG. 4 is an enlarged view partially illustrating an insulation resistance tester according to an embodiment of the present disclosure.

FIG. 5 is a schematic view illustrating an insulation resistance tester according to an embodiment of the present disclosure:

FIGS. 6A and 6B are perspective views each illustrating a test unit according to an embodiment of the present disclosure:

FIG. 7 is a perspective view illustrating an upper portion of a test unit according to an embodiment of the present disclosure;

FIG. 8 is a view illustrating a state where a test unit according to an embodiment of the present disclosure tests for insulation resistance;

FIG. 9 is a view illustrating a state where a test unit according to an embodiment of present disclosure is brought into contact with a pad.

FIG. 10 is a flowchart illustrating a method of controlling an insulation resistance tester according to an embodiment of the present disclosure; and

FIGS. 11A and 11B are views each illustrating a state where a test probe of a insulation resistance tester according to an embodiment of the present disclosure and an aluminum layer of a pouch cell are brought into contact with each other.

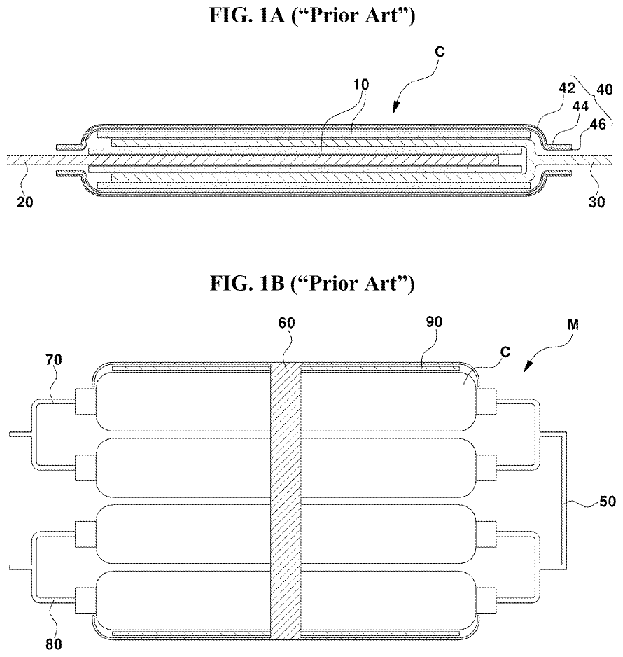

### DETAILED DESCRIPTION

Embodiments of the present disclosure will be described below only in an exemplary manner in terms of specific structures and functions. The embodiment of the present disclosure may be practiced in various forms without departing from the nature and gist of the present disclosure. The present disclosure should not be construed as being limited to the embodiments described in the specification. All alterations, equivalents, and substitutes that are included within the technical idea of the present disclosure should be understood as falling within the scope of the present disclosure.

In the present specification, the terms first, second, and so on are used to describe various constituent elements, but the various constituent elements are not limited to those terms. Those terms are used only to distinguish one constituent element from another. For example, a first constituent element may be termed a second constituent element without departing from the scope of each claim that defines the present disclosure. Likewise, the second constituent element may also be termed the first constituent element.

It should be understood that a constituent element, when referred to as being “coupled to” or “connected to” a different constituent element, may be directly coupled to or directly connected to the different constituent element without or with an intervening constituent element being present therebetween. In contrast, it should be understood that a constituent element, when referred to as being “directly coupled to” or “directly connected to” a different constituent element without an intervening constituent element being present therebetween. Expressions such as “between” and “directly between,” and “adjacent to” and “directly adjacent to” for describing a relationship between constituent elements should be construed in the same manner.

Like reference numerals depict like constituent elements throughout the present specification. Throughout the present specification, the terms that are used for describing embodiments do not impose any limitation on the present disclosure. Unless specified otherwise throughout the present specification, a singular noun or a singular noun phrase may have a plural meaning. The terms “comprise” and/or “comprising” are intended to indicate that a named constituent element, step, operation, or element is present, without precluding the presence or addition of one or more other constituent elements, steps, operations, or elements.

The present disclosure will be described in detail below with reference to the accompanying drawings.

As described above, as a cell packaging material, a pouch 40 includes an outer insulation layer 42, an aluminum layer 44, and an inner insulation layer 46. The outer insulation layer 42 is provided to protect a cell C from external impact and may be formed of polyethylene terephthalate (PET) resin. The aluminum layer 44 serves as a base material for maintaining mechanical strength and a barrier layer against oxygen and moisture. The inner insulation layer 46 serves as a sealant and may be formed of, for example, polypropylene (PP) or the like.

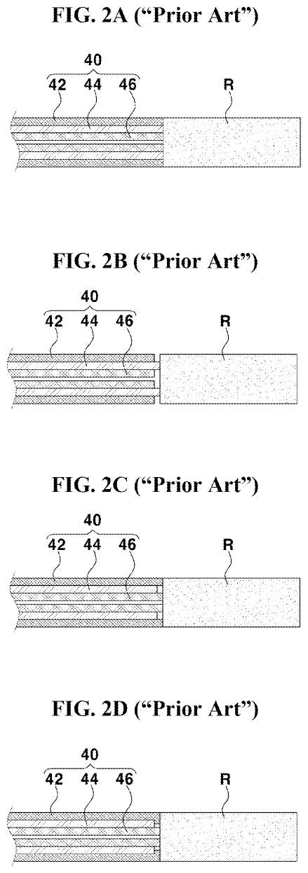

Testing for insulation resistance is performed by bringing a test probe R made of a solid material, such as conductive rubber, into contact with a cross section of an end portion of the pouch 40, particularly, with the aluminum layer 44 exposed through the cross section of the end portion thereof. As illustrated in FIGS. 2A to 2D, the pouch 40 is sealed by overlapping two films having the outer insulation layer 42, the aluminum layer 44, and the inner insulation layer 46.

As illustrated in FIG. 2A, in most cases, the test probe R is normally brought into the outer insulation layer 42, the aluminum layer 44, and the inner insulation layer 46 that are aligned with each other at the cross section of the end portion of the pouch 40. Even when the outer insulation layer 42, the aluminum layer 44 and the inner insulation layer 46 are not aligned with each other, the test probe R may be normally make a contact with the aluminum layer 44 if the aluminum layer 44 protrudes more outward than the outer insulation layer 42 and the inner insulation layer 46, as illustrated in FIG. 2B.

However, as illustrated in FIG. 2C, in some cases, the aluminum layer 44 may be recessed inward from the cross section of the end portion of the pouch 40. In another case, as illustrated in FIG. 2D, the outer insulation layer 42 or the inner insulation layer 46 is pushed outward, and thus the aluminum layer 44 is hidden from the end cross-section of the pouch 40. In these circumstances, the test probe R cannot be brought into contact with the aluminum layer 44.

As discussed above, it is not easy to bring the test probe R into contact with the thinned aluminum layer 44 exposed at the cross section of the end portion of the pouch 40. The occurrence of this failure of contact decreases an operating rate of mass production equipment. The reason for this is because when the failure of a contact between the test probe R and the aluminum layer 44 occurs, the test probe R needs to be moved upward and downward and then to be re-brought into contact at a different position.

To deal with this problem, according to the present disclosure, there is provided an insulation resistance tester that is capable of facilitating and improving a contact between a test probe and an aluminum layer at a cross section of a pouch when testing for insulation resistance of a pouch to an individual cell inside a battery module.

According to the present disclosure, in order to improve the reliability of the testing for insulation resistance, the operating rate at an testing section in a mass production line is prevented from being decreased due to the failure of a contact between the pouch and the test probe for the testing for insulation resistance, and the ability to make constant contact with the test probe is secured regardless of the packaging material or a state of the cross section of the pouch (the state refers to whether the aluminum layer is aligned, protrudes, or recessed).

The insulation resistance tester according to the present disclosure can solve the above-mentioned problem using a liquid contact technique. Specifically, according to the present disclosure, in order to solve a problem with a testing technique in the related art, the test probe and the aluminum layer are brought into contact with each other through a conductive solution.

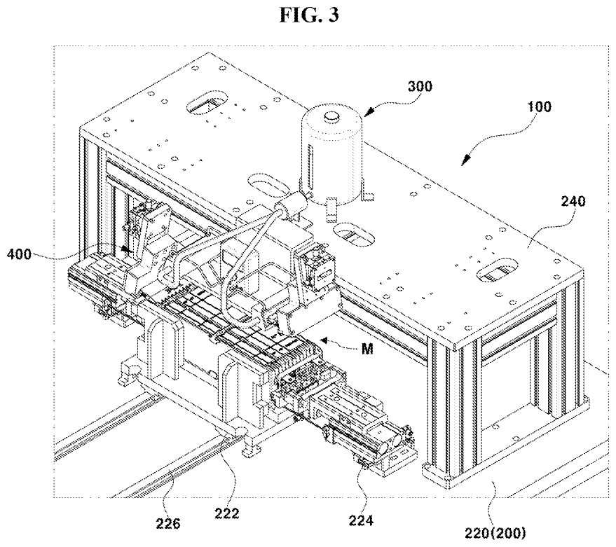

As illustrated in FIG. 3, an insulation resistance tester 100 includes a solution supply unit 300 and a test unit 400. In some embodiments, the insulation resistance tester 100 may be provided on a platform 200. For operational convenience, the platform 200 is positioned over the ground and is not limited in shape. In an embodiment, the platform 200 may include a base 220 and an elevation board 240.

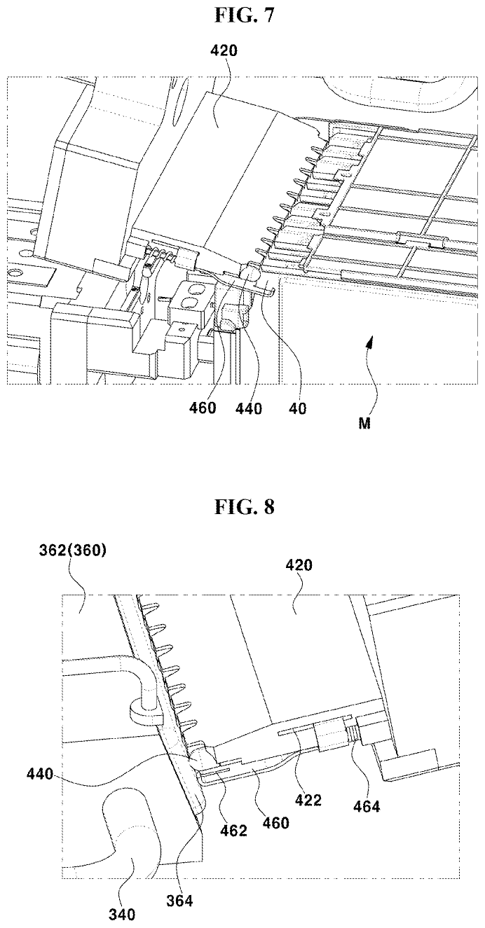

A test support 222 and a fixation unit 224 are provided on the base 220. The module M (FIG. 7), a target for the testing for insulation resistance, is mounted on the test support 222. The module M here is in a semi-finished state.

The test support 222 may be configured to be movable along the base 220. For example, a rail 226 that guides movement of the test support 222 may be provided on the base 220. The testing for insulation resistance is performed at a test position on the base 220. The test support 222 can move the module M to and from the test position, with the module M mounted thereon.

The fixation unit 224 may be provided to opposing sides of the test position on the base 220. The fixation unit 224 is configured to securely hold or grip the module M mounted on the test support 222 at the test position.

The elevation board 240 may be provided at a higher position than the base 220. The solution supply unit 300 may be mounted on the elevation board 240. In addition, the test unit 400 may be movably mounted on the elevation board 240. The test unit 400 may be configured to receive the conductive solution from the solution supply unit 300 provided on the elevation board 240 and to be movable to the test position.

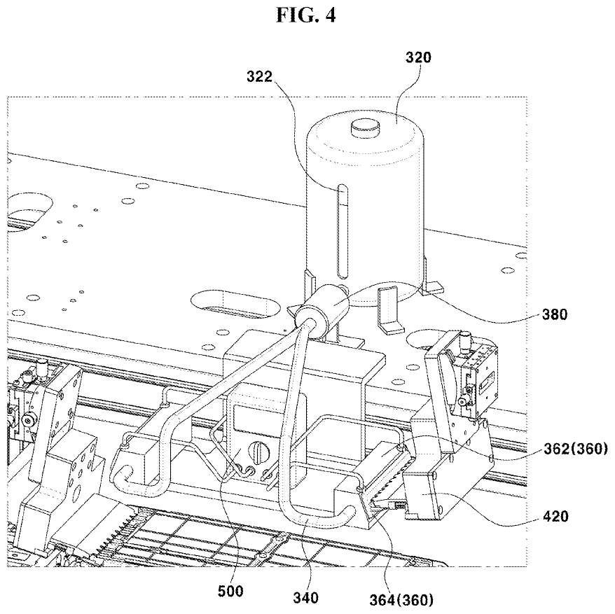

With reference to FIG. 4, the solution supply unit 300 is configured to supply the conductive solution to the test unit 400. The conductive solution is stored in a storage container 320 of the solution supply unit 300. The conductive solution is selected from among volatile solutions. Therefore, although falling on the inside or outside of the module M, the conductive solution soon evaporates. Thus, an influence of the conductive solution on the performance of the module M can be minimized.

An amount display unit 322 is provided on the storage container 320. The amount display unit 322 is configured to display an amount of the conductive solution remaining inside the storage container 320. In some embodiments, the amount display unit 322 may be a transparent window through which the inside of the storage container 320 can be seen. In some embodiments, the amount display unit 322 may be configured to display in analog or digital format a volume of the conductive solution remaining inside the storage container 320.

The conductive solution stored in the storage container 320 is supplied to a dispenser 360. In some embodiments, the storage container 320 and the dispenser 360 are configured to communicate with each other through a supply pipe 340. The dispenser 360 includes a frame 362 and a pad 364.

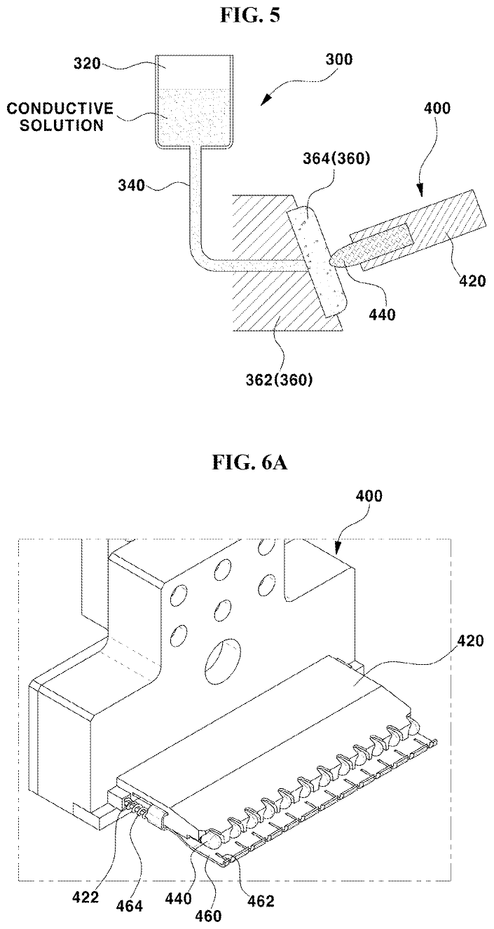

As schematically illustrated in FIG. 5, the frame 362 serves as a frame of the dispenser 360, and the supply pipe 340 is connected to the frame 362. The pad 364 is mounted on the frame 362. The conductive solution supplied to the dispenser 360 through the supply pipe 340 is configured to wet the pad 364. The pad 364 may be formed of a material, such as phylum porifera or sponge, although it is not so limited.

According to an embodiment of the present disclosure, the solution supply unit 300 includes an adjustment valve 380. The adjustment valve 380 may be arranged on the supply pipe 340 or between the storage container 320 and the supply pipe 340. When a preset condition is satisfied, the adjustment valve 380 may cause the conductive solution supplied to the dispenser 360 to flow back into the storage container 320. In addition, when a preset certain condition is satisfied, the adjustment valve 380 may cause the conductive solution to be supplied from the storage container 320 to the dispenser 360. The adjustment valve 380 may be a motor-driven valve, although it is not so limited.

The test unit 400 is supplied with the conductive solution from the solution supply unit 300. The supplied conductive solution is lightly applied to a test-target portion in such a manner as to form a contact between the test probe 440 and the aluminum layer 44. The test unit 400 may include a holder 420 and the test probe 440. A plurality of test probes 440 may be provided on one holder 420. In some embodiments, as many test probes 440 as the number of pouch-type cells C inside the module M may be provided.

The holder 420 may ascend or descend with respect to the base 220. In some embodiments, the holder 420 may be configured to move leftward and rightward with respect to the base 220. The holder 420 is configured in a manner that can move the test unit 400 in order that no interference occurs when the battery module M, the test target, is mounted on and is detached from the test support 222. In some embodiments, the holder 420 may be configured in a manner that is manually movable. Alternatively, the holder 420 may be configured to receive electric power to be automatically movable.

The holder 420 is configured to grip the test probe 440. The test probe 440 gripped by the holder 420 is arranged to reach the dispenser 360 or the pad 364. The test probe 440 is configured to be brought into contact with the pad 364 to transfer the conductive solution from the pad 364 to the test probe 440. According to the present disclosure, as is the case with a gap filler, a gap that may occur between the aluminum layer 44 and the test probe 440 can be filled with the conductive solution to create a contact between the aluminum layer 44 and the test probe 440. In addition, the contact through the conductive solution can prevent damage due to a direct contact between the test probe 440 and a pouch cell C.

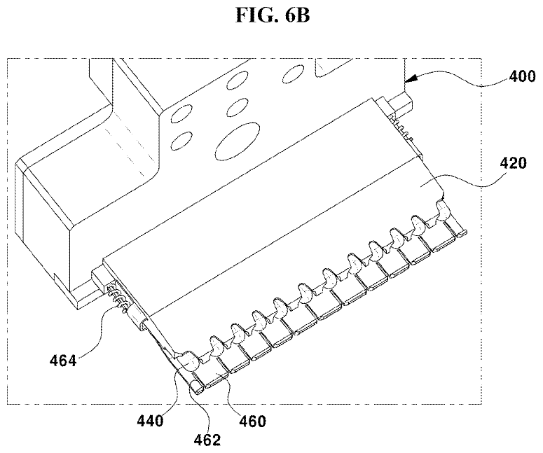

With reference to FIGS. 6A and 6B, according to some embodiments of the present disclosure, the test unit 400 may further include a guard member 460. The guard member 460 is configured to prevent or minimize dropping of the conductive solution transferred by the test probe 440 into the module M while the holder 420 is moved or while the testing for insulation resistance is performed. For example, when the test probe 440 approaches the module M, the conductive solution transferred by the test probe 440 is prevented from flowing into the module M and thus causing a short circuit between unit cells. In an embodiment, the guard member 460 is arranged under the test probe 440.

The guard member 460 may include an insertion portion 462. The insertion portion 462 may be formed on an end portion of the guard member 460. Preferably, the insertion portion 462 may be a groove cut into the end portion of the guard member 460.

The guard member 460 may include a plurality of insertion portions 462, and the plurality of insertion portions 462 may be arranged to be spaced a predetermined distance apart. Particularly, the insertion portion 462 may be substantially aligned with the test probe 440. For example, the insertion portion 462 may be provided below the test probe 440 in a manner that is substantially parallel with the test probe 440. In some embodiments, the insertion portion 462 is configured in such a manner that at least some portions thereof are overlapped with the test probe 440 in a state of being in parallel with the test probe 440.

As illustrated in FIG. 7, while the testing for insulation resistance is performed, when the test probe 440 is brought into contact with the end portion of the pouch 40, the end portion of the pouch 40 may be inserted into the insertion portion 462. Therefore, during the testing, the guard member 460 may be prevented from interfering with the module M, the test target.

In addition, as perhaps best illustrated in FIG. 8, the guard member 460 may have a structure that makes the guard member 460 retractable. Specifically, the guard member 460 can retract into the holder 420. When an external force is applied toward the insertion portion 462, the guard member 460 can be moved into the holder 420. To this end, in some embodiments, the guard member 460 is configured to be movable inside a guard groove 422 provided in the holder 420. When the external is removed, the guard member 460 is provided with a restoring force from an elastic member 464 provided on the guard member 460 and thus returns to an original position thereof. The structure that makes the guard member 460 retractable can prevent the guard member 460 from undergoing interference when the test probe 440 of the holder 420 approaches the dispenser 360 and is supplied with the conductive solution from the pad 364.

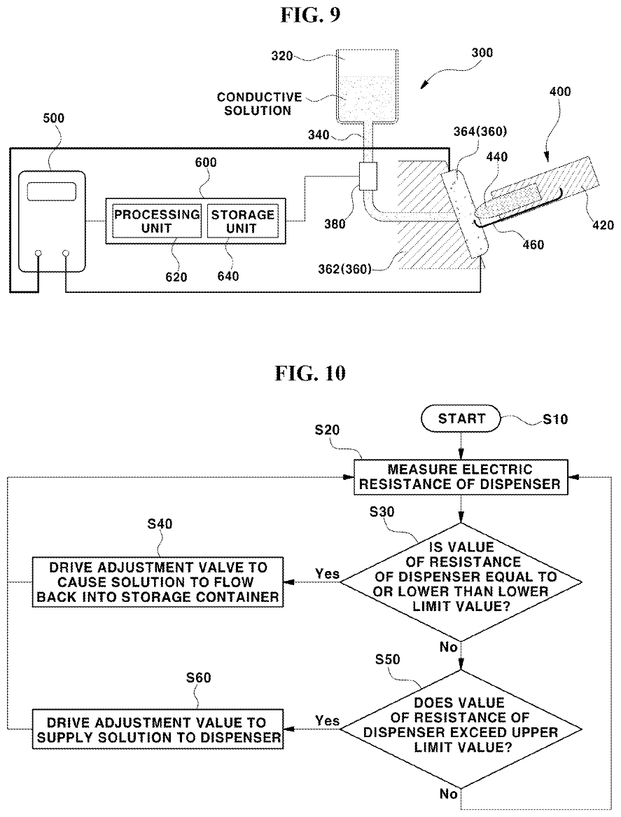

As illustrated in FIG. 9, according to some embodiments of the present disclosure, the extent to which the pad 364 of the dispenser 360 is wetted can be controlled. To this end, the insulation resistance tester 100 may further include a measurement unit 500 and a controller 600.

The measurement unit 500 is configured to measure electric resistance of the dispenser 360 or the pad 364. Particularly, the measurement unit 500 is configured to measure the electric resistance of the pad 364 in real time and to transfer the measurements to the controller 600 during the testing.

The controller 600 is configured to obtain measurement information of the electric resistance from the measurement unit 500 and to control the adjustment valve 380 on the basis of the measured electric resistance.

The controller 600 may include a processing unit 620 and a storage unit 640. The storage unit 640 is configured to store a sequence of executable commands on the basis of the measured electric resistance. The processing unit 620 is configured to execute the commands from the storage unit 640. For example, in a case where the measured electric resistance exceeds a preset upper limit, the processing unit 620 receives commands satisfying this condition from the storage unit 640 and executes the received commands. For example, when the measured electric resistance is at or below a preset lower limit, it can be determined that the pad 364 is in a state where the conductive solution is excessively supplied. Thus, the processing unit 620 controls the adjustment valve 380 to cause the conductive solution in the pad 364 to flow back toward the storage container 320. Conversely, when the measured electric resistance exceeds the preset upper limit value, it can be determined that a portion of the conductive solution in the dispenser 360 evaporates and thus that the dispenser 360 is in a state where the amount of conductive solution supplied is insufficient. Therefore, the processing unit 620 controls the adjustment valve 380 in such a manner that the conductive solution in the storage container 320 is supplied to the pad 364.

An appropriate resistance range may be set to 30 kiloohms (kΩ) to 160 kΩ, although it is not so limited. For example, in a case where a value of the measured electric resistance is approximately 20 kΩ, it can be determined that the conductive solution is excessively supplied to the pad 364. Conversely, in a case where the value of the measured electric resistance is, for example, approximately 180 kΩ, it can be determined that the conductive solution is insufficient in the pad 364 such that the conductive solution is supplied from the storage container 320 to the pad 364.

As illustrated in FIG. 10, the extent to which the pad 364 of the dispenser 360 is wetted with the conductive solution can be controlled. Control is started at S10.

While the testing for insulation resistance is performed, the measurement unit 500 continuously monitors electric resistance of the dispenser 360 at S20. Then the measurement unit 500 transfers the measured electric resistance to the controller 600.

The controller 600 compares a value of the measured electric resistance of the dispenser 360 with limits including the upper limit and the lower limit, that are stored in the storage unit 640 at S30. If the value of the measured electric resistance of the dispenser 360 is equal to or lower than the lower limit, the dispenser 360 is in the state where the conductive solution is excessively supplied. Therefore, by driving the adjustment valve 380, the controller 600 causes the conductive solution in the dispenser 360 to flow back into the storage container 320 at S40.

Conversely, in a case where it is determined that the value of the measured electric resistance of the dispenser 360 exceeds the upper limit at S50, the dispenser 360 is in the state where the conductive solution is insufficiently supplied. Therefore, by driving the adjustment valve 380, the controller 600 causes the conductive solution in the storage container 320 to flow to the dispenser 360 at S60.

The test unit 400 is connected to the controller 600. The controller 600 is configured to receive insulation resistance measured by the test probe 440 and to determine on the basis of the received insulation resistance whether or not the inspection resistance is normal. This function of testing for insulation resistance may be performed also by the controller 600 that operates the adjustment valve 380 according to the electric resistance of the pad 364 or may be performed by a separate controller.

In some embodiments, the testing for insulation resistance by the insulation resistance tester 100 according to the present disclosure may be performed as follows. First, conductivity testing may be performed. It is checked whether or not the test probe 440 and the aluminum layer 44 of the pouch cell C are normally brought into contact with each other. For example, in a case where a signal transmitted by the controller 600 is received by the controller 600 itself through the aluminum layer 44, it can be determined that the test probe 440 and the aluminum layer 44 successfully conduct electricity.

Next, the testing for insulation resistance is performed. For example, when the electric resistance measured by the test probe 440 exceeds 100 megaohms (MΩ), the controller 600 can determine that a target cell operates normally. Conversely, when the electric resistance measured by the test probe 440 is equal to or lower than 100 MΩ, the controller 600 can determine that the target cell malfunctions.

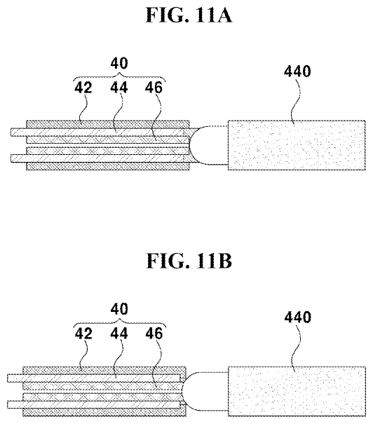

As illustrated in FIGS. 11A and 11B, according to the present disclosure, regardless of the contact state between the end portion of the pouch and the test probe 440, the contact between the test probe and the aluminum layer of the end portion of the pouch cell can be established when testing for insulation resistance of the pouch to an individual cell inside the battery module.

Regardless of what state the end portion of the pouch cell is in, the insulation resistance tester according to the present disclosure can make a contact between the aluminum layer of the pouch cell and the test probe. Thus, the reliability of the testing for insulation resistivity can be improved.

According to the present disclosure, the operating rate at the testing section in the mass production line can be prevented from being decreased due to the failure of the contact between the pouch and the test probe.

The insulation resistance tester according to the present disclosure performs the testing for insulation resistance more simply and easily than in an existing process of testing for insulation resistance. In the existing process, by measuring vision, temperature, ultraviolet light, infrared light, and weight, it is determined whether or not the insulation resistance is normal. The insulation resistance tester according to the present disclosure that performs a simpler process of testing for insulation resistance makes it possible to facilitate configuration of automation equipment for battery module production.

The insulation resistance tester according to the present disclosure that has a simple structure incurs relatively low investment cost and ensures high-quality testing for insulation resistance. Furthermore, an improvement in quality and cost saving can be both achieved.

The present disclosure is not limited to the embodiments described above and the accompanying drawings. It would be apparent to a person of ordinary skill in the art to which the present disclosure pertains that substitutions, modifications, and alterations are possible without departing from the technical idea of the present disclosure.

What is claimed is:

1. An insulation resistance tester comprising:
a solution supply unit; and
a test unit configured to receive a conductive solution from the solution supply unit, and to establish contact with a test target through the conductive solution to measure an insulation resistance of the test target.

2. The insulation resistance tester of claim 1, wherein the solution supply unit is a pad wetted with the conductive solution.

3. The insulation resistance tester of claim 2, wherein the solution supply unit comprises:
a storage container configured to store the conductive solution;
a supply pipe configured to fluidly communicate the storage container with the pad; and
an adjustment valve configured to switch a flow direction of the conductive solution between the storage container and the pad.

4. The insulation resistance tester of claim 1, wherein the test unit comprises:
a test probe configured to measure the insulation resistance; and
a holder configured to hold the test probe securely.

5. The insulation resistance tester of claim 4, wherein the test unit comprises:
a guard member movably mounted on the holder and positioned under the test probe.

6. The insulation resistance tester of claim 5, wherein the test unit further comprises:
a guide groove formed in the holder configured to guide movement of the guard member; and
an elastic member interposed between the holder and the guard member and configured to provide a restoring force to the guard member.

7. The insulation resistance tester of claim 6, wherein the guard member comprises:
an insertion portion positioned below the test probe to at least partially overlap with the test probe in parallel with the insertion portion, wherein the test target is insertable into the insertion portion.

8. The insulation resistance tester of claim 1, wherein the test target is an end portion of a cell packaging material in which a battery cell is accommodated.

9. The insulation resistance tester of claim 1, further comprising:
a platform supporting the solution supply unit and the test unit;
a test support configured to be movable on the platform and to mount the test target thereon; and
a fixation unit configured to grip the test target at a test position on the test support.

10. The insulation resistance tester of claim 9, wherein the solution supply unit is positioned above the test support at the platform, and wherein the test unit is configured to be movable between the solution supply unit and the test support.

11. An insulation resistance tester comprising:
a pad wetted with a conductive solution;
a test unit configured to be supplied with the conductive solution from the pad and to make a contact with a test target through the conductive solution to measure insulation resistance of the test target; and
a first controller configured to receive the measured insulation resistance from the test unit and to determine whether the insulation resistance is normal.

12. The insulation resistance tester of claim 11, further comprising:
a measurement unit configured to measure electric resistance of the pad.

13. The insulation resistance tester of claim 12, further comprising:
a second controller configured to receive the measured insulation resistance from the measurement unit and to determine whether the insulation resistance is normal.

14. The insulation resistance tester of claim 13, wherein the first controller and the second controller are integrated into one controller.

15. A method of controlling an insulation resistance tester including steps implemented by a controller, the method comprising:
receiving in real time electric resistance of a pad supplied with a conductive solution from a storage container;
comparing the received electric resistance with preset limits; and
controlling, based on a result of the comparison, an adjustment valve configured to switch a flow direction of the conductive solution between the storage container and the pad.

16. The method of claim 15, wherein the controlling the adjustment valve comprises:
driving the adjustment valve to supply the conductive solution from the storage container to the pad when the received electric resistance exceeds an upper limit of the preset limits.

17. The method of claim 15, wherein the controlling the adjustment valve comprises:
driving the adjustment valve such that the conductive solution in the pad flows back into the storage container when the received electric resistance is at or below a lower limit of the preset limit.
